(19) United States
(12) Patent Application Publication
(10) Pub. No.: US 2026/0311673 A1
(43) Pub. Date: Oct. 8, 2026

(54) NOISE REDUCTION EARPHONE AND EARPHONE NOISE REDUCTION METHOD

(71) Applicant: Shenzhen Dancing Future Technology Ltd., Shenzhen (CN)

(72) Inventors: Chuanbo WANG, Shenzhen (CN); Qifeng CHEN, Shenzhen (CN); Hongguo DENG, Shenzhen (CN)

(21) Appl. No.: 19/480,762

(22) PCT Filed: Jun. 28, 2024
(86) PCT No.: PCT/CN2024/102733

§ 371 Date: Oct. 31, 2025

(30) Foreign Application Priority Data
Jun. 30, 2023 (CN) 202310793898.1

(51) Int. Cl. G10K 11/178; H03G 3/30; H04R 1/10

(52) U.S. Cl. CPC G10K 11/17825; G10K 11/17823; G10K 11/17881; H03G 3/3005; H04R 1/1008; H04R 1/105; H04R 1/1075; H04R 1/1083; G10K 2210/1081; G10K 2210/3026; G10K 2210/3027; G10K 2210/3028; G10K 2210/3056; G10K 2210/3215; G10K 2210/506; H03G 2201/103; H04R 2460/01

(57) ABSTRACT

The present application discloses a noise reduction earphone, which includes a sound emitting apparatus, where the sound emitting apparatus includes: a cavity, an electroacoustic transducer, a first microphone, a second microphone, and a signal processing unit, the electroacoustic transducer divides the cavity into a first cavity and a second cavity, the first cavity is provided with a first sound outlet hole, and the second cavity is provided with a second sound outlet hole; the signal processing unit includes a first signal processing circuit, a second signal processing circuit, and a first adder, the two signal processing circuits perform signal processing on the two electrical signals to obtain two electrical signals with equal amplitudes and opposite phases; and the first adder processes the two electrical signals, and a signal transmitted to the electroacoustic transducer is zero.

The present application claims priority to Chinese Patent Application No. 202310793898.1, filed with the China National Intellectual Property Administration on Jun. 30, 2023 and entitled “NOISE REDUCTION EARPHONE AND NOISE REDUCTION METHOD THEREOF”, which is incorporated herein by reference in its entirety.

### TECHNICAL FIELD

The present application relates to a sound emitting apparatus, and more particularly, to a noise reduction earphone and a earphone noise reduction method.

### BACKGROUND

In the related art, in a feedforward noise reduction system of an in-ear or semi in-ear noise reduction earphone, a second microphone or a second microphone sound pickup hole is arranged as far as possible from a sound emitted by an electroacoustic transducer, for example, the electroacoustic transducer emits sound energy through a first sound outlet hole, a second sound outlet hole, a tuning hole or the like of an audio apparatus, so as to avoid the occurrence of howling. Because the sound of such an earphone enters the ear canal through the sound outlet hole and has a small sound energy radiated outward, the occurrence of howling can be avoided when the second microphone is arranged away from the tuning hole or the sound outlet hole of the earphone. However, in the feedforward noise reduction system of an open audio apparatus, the second microphone very easily picks up sounds emitted from the first sound outlet hole and the second sound outlet hole, thereby forming a positive feedback system in some frequency bands of 10 Hz to 20000 Hz and causing howling.

### SUMMARY

An object of the present disclosure is to provide a noise reduction earphone and an earphone noise reduction method to solve the problem of excessive howling of the current earphone.

In a first aspect, the present disclosure discloses a noise reduction earphone, which includes a sound emitting apparatus, where the sound emitting apparatus includes: a cavity, an electroacoustic transducer, a first microphone, a second microphone, and a signal processing unit;
the electroacoustic transducer is arranged in the cavity and divides the cavity into a first cavity and a second cavity, a first sound outlet hole is arranged in the first cavity, and a second sound outlet hole is arranged in the second cavity;
the first microphone is arranged in the first cavity and is configured to collect a sound signal of the electroacoustic transducer in the first cavity and convert the sound signal into an electrical signal S1;
the second microphone is arranged close to the second sound outlet hole and is configured to collect a sound signal of the electroacoustic transducer in the second cavity and convert the sound signal into an electrical signal S2;
the signal processing unit includes a first signal processing circuit, a second signal processing circuit, and a first adder, the first signal processing circuit is configured to perform signal processing on the electrical signal S1, a processed electrical signal is S11, the second signal processing circuit is configured to perform signal processing on the electrical signal S2, a processed electrical signal is S12, and the electrical signal S11 and the electrical signal S12 have equal amplitudes and opposite phases; and the first adder is configured to process the electrical signal S11 and the electrical signal S12, a processed electrical signal is S3, the electrical signal S3 is transmitted to the electroacoustic transducer as an output signal of the signal processing unit, and an amplitude of the electrical signal S3 is zero.

In a second aspect, the present disclosure discloses a earphone noise reduction method, which is applied to a noise reduction earphone, where the noise reduction earphone includes an electroacoustic transducer, a first microphone, a second microphone, and a signal processing unit, the signal processing unit includes a first signal processing circuit, a second signal processing circuit, and a first adder, the first microphone is configured to collect a sound signal of the electroacoustic transducer in a first cavity and convert the sound signal into an electrical signal S1, the second microphone is configured to collect a sound signal of the electroacoustic transducer in a second cavity and convert the sound signal into an electrical signal S2, and the method includes the following steps:
collecting, by the first microphone, the sound signal of the electroacoustic transducer in the first cavity and converting the sound signal into the electrical signal S1;
collecting, by the second microphone, the sound signal of the electroacoustic transducer in the second cavity and converting the sound signal into the electrical signal S2;
performing, by the first signal processing circuit, signal processing on the electrical signal S1, where a processed electrical signal is S11, and performing, by the second signal processing circuit, signal processing on the electrical signal S2, where a processed electrical signal is S12, and the electrical signal S11 and the electrical signal S12 have equal amplitudes and opposite phases; and
processing, by the first adder, the electrical signal S11 and the electrical signal S12, where a processed electrical signal is S3, and transmitting the electrical signal S3 to the electroacoustic transducer as an output signal of the signal processing unit, where an amplitude of the electrical signal S3 is zero.

With reference to the above technical solution, in the present disclosure, the first adder is configured to process the electrical signal S11 and the electrical signal S12, the processed electrical signal is S3, the electrical signal S3 is transmitted to the electroacoustic transducer as the output signal of the signal processing unit, and the amplitude of the electrical signal S3 is zero. In the present solution, the signal processing unit is provided with a processing circuit, and when an external sound wave signal is equivalent to 0, this condition may be approximately obtained in an anechoic chamber, the electrical signal S1 and the electrical signal S2 are adjusted by the first processing circuit and the second processing circuit to have completely equal amplitudes and completely opposite phases, and a signal transmitted externally after the two signals are added is zero. At this time, in the noise reduction system, the sound signals of the electroacoustic transducer received by the first microphone 13 and the second microphone 14 are cancelled in a noise reduction loop and are not transmitted back to the electroacoustic transducer, thereby avoiding a cycle in which the microphone receives the sound of the electroacoustic transducer to generate an electrical signal, and the electrical signal is transmitted back to the electroacoustic transducer to generate a sound signal which is transmitted to the microphone, thus avoiding the occurrence of howling.

### BRIEF DESCRIPTION OF DRAWINGS

FIG. 1 is a schematic diagram of an overall structure of a first embodiment of a noise reduction earphone according to the present disclosure;

FIG. 2 is a schematic diagram of wearing of the first embodiment of the noise reduction earphone according to the present disclosure;

FIG. 3 is a schematic diagram of a circuit structure of the first embodiment of the noise reduction earphone according to the present disclosure;

FIG. 4 is a schematic diagram of a circuit structure of a fourth embodiment of the noise reduction earphone according to the present disclosure;

FIG. 5 is a schematic diagram of a circuit structure of a fifth embodiment of the noise reduction earphone according to the present disclosure;

FIG. 6 is a schematic diagram of a circuit structure of a sixth embodiment of the noise reduction earphone according to the present disclosure;

FIG. 7 is a schematic diagram of another circuit structure of the sixth embodiment of the noise reduction earphone according to the present disclosure;

FIG. 8 is a schematic diagram of a circuit structure of another noise reduction earphone according to the present disclosure;

FIG. 9 is a schematic diagram of a circuit structure of an eighth embodiment of another noise reduction earphone according to the present disclosure;

FIG. 10 is a schematic diagram of a circuit structure of a ninth embodiment of another noise reduction earphone according to the present disclosure;

FIG. 11 is a schematic diagram of a circuit structure of a tenth embodiment of another noise reduction earphone according to the present disclosure;

FIG. 12 is a schematic diagram of another circuit structure of the tenth embodiment of another noise reduction earphone according to the present disclosure;

FIG. 13 is a schematic diagram of a structure of an eleventh embodiment of another noise reduction earphone according to the present disclosure;

FIG. 14 is a schematic diagram of a principle structure of a dipole sound source;

FIG. 15 is a schematic diagram of a principle structure of a quadrupole sound source;

FIG. 16 is a schematic diagram of transfer function-amplitude frequency comparison of another noise reduction earphone according to the present disclosure without a first tuning hole;

FIG. 17 is a schematic diagram of transfer function-amplitude frequency comparison of another noise reduction earphone according to the present disclosure with a first tuning hole or a sound short circuit tube;

FIG. 18 is a schematic diagram of a resonance frequency formed by a first cavity and a first sound outlet hole;

FIG. 19 is a schematic diagram of a structure of another noise reduction earphone according to the present disclosure;

FIG. 20 is a schematic flowchart of a first embodiment of an earphone noise reduction method according to the present disclosure;

FIG. 21 is a schematic diagram of a structure of an ear;

FIG. 22 is a relative position relationship between oncoming wind and a noise reduction earphone; and

FIG. 23 is a relative position relationship between the oncoming wind and the noise reduction earphone at another angle.

### DETAILED DESCRIPTION

In the embodiments of the present disclosure, the term “and/or” describes an association relationship between associated objects, and represents that three relationships may exist, for example, A and/or B may represent the following three cases: only A exists, both A and B exist, and only B exists. The character “/” generally indicates an “or” relationship between the associated objects.

In the embodiments of the present disclosure, the term “multiple” refers to two or more, and other quantifiers are similar thereto.

The technical solutions in the embodiments of the present disclosure will be described clearly and comprehensively with reference to the drawings in the embodiments of the present disclosure. Obviously, the described embodiments are only some embodiments of the present disclosure, rather than all the embodiments. All other embodiments obtained by a person of ordinary skill in the art based on the embodiments of the present disclosure without creative efforts shall fall within the protection scope of the present disclosure.

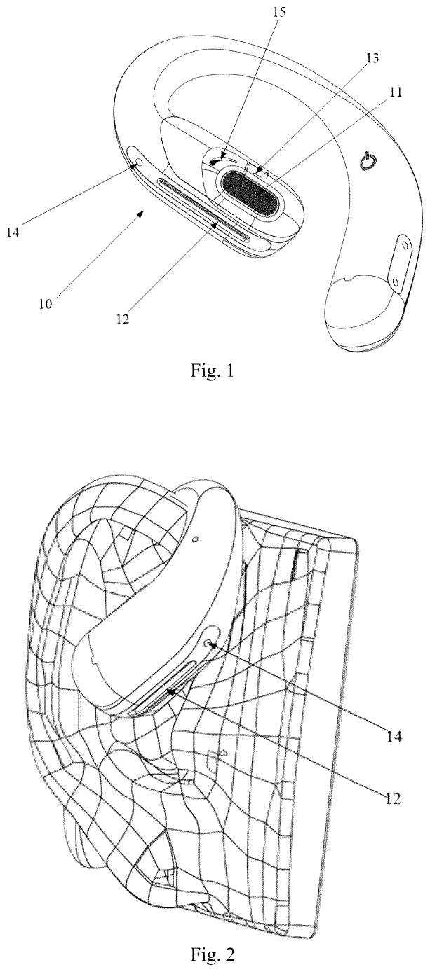

The present application provides a noise reduction earphone. Referring to FIG. 1 to FIG. 3, the noise reduction earphone according to the embodiments of the present disclosure includes a sound emitting apparatus 10, and the sound emitting apparatus 10 includes: a cavity, an electroacoustic transducer, a first microphone 13, a second microphone 14, and a signal processing unit. The electroacoustic transducer divides the cavity into a first cavity and a second cavity, and a first sound outlet hole 11 and a second sound outlet hole 12 are respectively arranged in the first cavity and the second cavity. Specifically, a diaphragm is arranged on the electroacoustic transducer, and the diaphragm vibrates back and forth to squeeze air in the first cavity and the second cavity to generate sounds, which are propagated through the first sound outlet hole 11 of the first cavity and the second sound outlet hole 12 of the second cavity, respectively. Due to the structure of the noise reduction earphone, when the diaphragm vibrates, sounds propagated out through the first sound outlet hole 11 and the second sound outlet hole 12 have substantially the same amplitude and substantially opposite phases. The reason why the two groups of sounds do not have completely the same amplitude and completely opposite phases is that there is a difference in acoustic resistance between the front and rear of the diaphragm of the electroacoustic transducer.

The first microphone 13 is arranged in the first cavity and is configured to collect a sound signal of the electroacoustic transducer in the first cavity and convert the sound signal into an electrical signal S1.

The second microphone 14 is arranged close to the second sound outlet hole 12 and is configured to collect a sound signal of the electroacoustic transducer in the second cavity and convert the sound signal into an electrical signal S2.

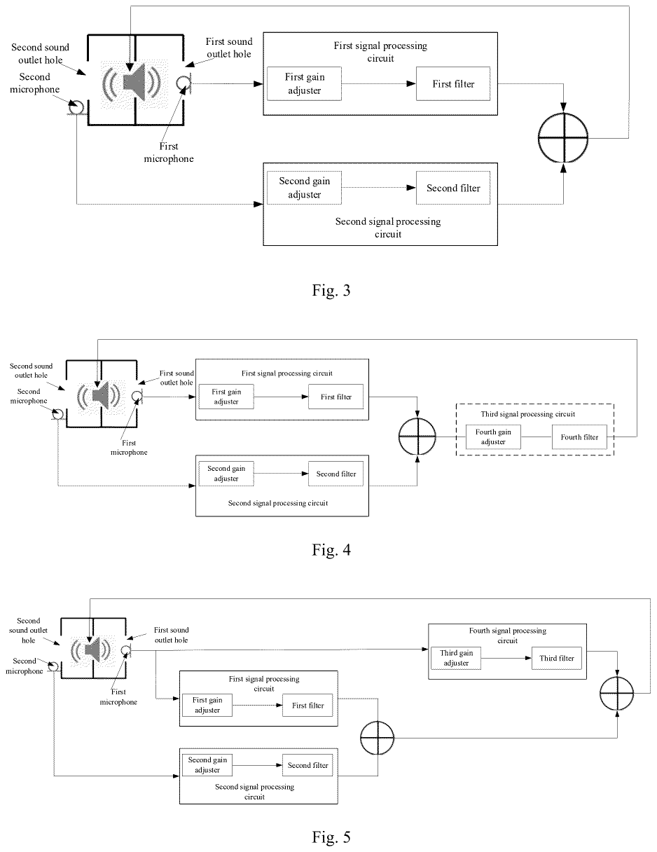

Referring to FIG. 3, the signal processing unit includes a first signal processing circuit, a second signal processing circuit, and a first adder, the first signal processing circuit is configured to process the electrical signal S1, a processed electrical signal is S11, the second signal processing circuit is configured to process the electrical signal S2, a processed electrical signal is S12, and the electrical signal S11 and the electrical signal S12 have equal amplitudes and opposite phases.

The first adder is configured to process the electrical signal S11 and the electrical signal S12, a processed electrical signal is S3, the electrical signal S3 is transmitted to the electroacoustic transducer as an output signal of the signal processing unit, and an amplitude of the electrical signal S3 is zero. In the present solution, the signal processing unit is provided with a processing circuit, and when an external sound wave signal is equivalent to 0, this condition may be approximately obtained in an anechoic chamber, the electrical signal S1 and the electrical signal S2 are adjusted by the first processing circuit and the second processing circuit to have completely equal amplitudes and completely opposite phases, and after the above two signals are added, a signal transmitted externally is zero. At this time, in the noise reduction system, sound signals of the electroacoustic transducer received by the first microphone 13 and the second microphone 14 are cancelled in a noise reduction loop and are not transmitted back to the electroacoustic transducer, thereby avoiding a cycle in which a microphone receives a sound of the electroacoustic transducer to generate an electrical signal, and the electrical signal is transmitted back to the electroacoustic transducer to generate a sound signal which is transmitted to the microphone, thus avoiding the occurrence of howling.

As an implementation, in the present embodiment, the first signal processing circuit includes a first gain adjuster and a first filter that are electrically connected, and the second signal processing circuit includes a second gain adjuster and a second filter that are electrically connected. A parameter of the first gain adjuster is Gain1, a parameter of the first filter is Filter1, a parameter of the second gain adjuster is Gain2, a parameter of the second filter is Filter2, the electrical signal S11=S1*Gain1*Filter1, the electrical signal

$$S 12 = S {2}^{*} {Gain 2}^{*} Filter 2 ,$$

and the electrical signal S3 satisfies:

$$S 3 = S {1}^{*} Gain {1}^{*} Filter 1 + S {2}^{*} {Gain 2}^{*} Filter 2 = 0 .$$

After the above condition is met, parameters of the first signal processing circuit and the second signal processing circuit are kept unchanged, and in the present embodiment, parameters of the first gain adjuster and the first filter, and the second gain adjuster and the second filter are kept unchanged, so that the electrical signal S3 satisfies the above condition.

In the present embodiment, a processing sequence of the first gain adjuster and the first filter for the electrical signal S1 is not limited, that is, the first gain adjuster may first process the electrical signal S1, and then the first filter processes the electrical signal processed by the first gain adjuster. The sequence may be reversed, that is, the first filter first processes the electrical signal S1, and then the first gain adjuster processes the electrical signal processed by the first filter. Similarly, this is applicable to the second gain adjuster and the second filter. In some solutions, the first gain adjuster and the first filter are integrated into one adjuster, and the adjuster may include functions of the first gain adjuster and the first filter, or the adjuster may adjust the electrical signal S1 or S2 to meet the above requirements, which also falls within the protection scope of the present solution. Similarly, this is applicable to the second gain adjuster and the second filter.

As an implementation, in the present embodiment, a center distance between a sound pickup hole of the first microphone 13 and the first sound outlet hole 11 may be set to not greater than 5 mm according to an actual situation.

A center distance between a sound pickup hole of the second microphone 14 and the second sound outlet hole 12 may also be set to not greater than 5 mm according to an actual situation.

In the design of a traditional noise reduction earphone, a sound pickup hole of the second microphone 14 is designed to be as far as possible from a sound outlet hole, that is, the microphone is designed to collect as little sound as possible emitted by the electroacoustic transducer and only collect external noise, and noise reduction design is performed based on this idea. In many noise reduction earphones, the second microphone 14 is designed at an acoustic zero position of an acoustic dipole radiation sound field formed by the first sound outlet hole 11 and the second sound outlet hole 12, so that the second microphone 14 cannot collect the sound emitted by the electroacoustic transducer at all. These designs lead to inaccurate noise determination of the noise reduction system, and fail to achieve a better noise reduction effect or cause howling. The technical path of the present solution is different from that of the above solution. In the present solution, the first microphone 13 is arranged as close as possible to the first sound outlet hole 11 and the second microphone 14 is arranged as close as possible to the second sound outlet hole 12, for example, a center distance between the sound pickup hole of the first microphone 13 and the first sound outlet hole 11 may be set to not greater than 5 mm according to an actual situation, and a center distance between a sound pickup hole of the second microphone 14 and the second sound outlet hole 12 may also be set to not greater than 5 mm according to an actual situation, so as to facilitate the collection of the sound of the first sound outlet hole 11 by the first microphone 13 and the collection of the sound of the second sound outlet hole 12 by the second microphone 14. As may be seen from the above solution, in the present embodiment, by arranging an anti-howling circuit, the sound signal collected by the first microphone 13 and the sound signal collected by the second microphone 14 are completely cancelled in the noise reduction system and are not transmitted back to the electroacoustic transducer. Compared with the solution of arranging the microphone away from the sound outlet hole, the present solution has better noise reduction and anti-howling effects.

In the present embodiment, after the electrical signal S1 and the electrical signal S2 are processed to obtain the electrical signal S11 and the electrical signal S12 which have equal amplitudes and opposite phases, the electrical signal S11 and the electrical signal S12 are processed by the first adder, thereby realizing that a signal transmitted to the electroacoustic transducer is zero, thus preventing the occurrence of howling.

Based on the first embodiment shown in FIG. 1 to FIG. 3, a second embodiment of the noise reduction earphone of the present disclosure is provided. The difference between the present embodiment and the first embodiment lies in that in the present embodiment, the first microphone 13 is further configured to collect an external sound signal and convert the external sound signal into an electrical signal N1, the second microphone 14 is further configured to collect an external sound signal and convert the external sound signal into an electrical signal N2; the first signal processing circuit is further configured to process the electrical signal N1, a processed electrical signal is N11, the second signal processing circuit is further configured to process the electrical signal N2, a processed electrical signal is N12, the first adder is further configured to process the electrical signal N11 and the electrical signal N12, a processed electrical signal is N3, and the electrical signal N3 is transmitted to the electroacoustic transducer as the output signal of the signal processing unit. That is, in the second embodiment, the noise reduction earphone is worn under normal conditions. The electrical signal N3 satisfies:

$$N 3 = N {1}^{*} {Gain 1}^{*} Filter 1 + N {2}^{*} {Gain 2}^{*} Filter 2 .$$

When the noise reduction earphone is in a normal working state, a signal of the first signal processing circuit is marked as S1N, and a signal of the second signal processing circuit is marked as S2N. When the noise reduction earphone is working normally, before the first adder, the signals of the first signal processing circuit and the second signal processing circuit are:

$$S 1 N = S {1}^{*} {Gain 1}^{*} Filter 1 + N {1}^{*} {Gain 1}^{*} Filter 1 ;$$

$$S 2 N = S {2}^{*} {Gain 2}^{*} Filter 2 + N {2}^{*} {Gain 2}^{*} Filter 2 ;$$

In the present embodiment, a signal N3 of a third signal path is calculated according to a signal S1N of a first signal path and a signal S2N of a second signal path.

After passing through the first adder, because S11 and S12 have the same amplitude and opposite phases, the signals of the electroacoustic transducer are completely cancelled and only an external sound wave is reserved, therefore, at this time, the signal N3 of the third signal path may be expressed as:

$$N 3 = N {1}^{*} {Gain 1}^{*} Filter 1 + N {2}^{*} {Gain 2}^{*} Filter 2 .$$

Then, an external sound wave signal N2 collected by the second microphone 14 is calculated according to the signal N3 of the third signal path:

$$N 2 = ( N 3 - N {1}^{*} Gain {1}^{*} Filter 1 ) / {Gain 2}^{*} Filter 2 .$$

At this time, the transmitted electrical signal N3 is not necessarily consistent with a target noise reduction signal, but may also prevent the occurrence of howling.

A noise signal in a target region (a space within a range from the first sound outlet hole 11 to an eardrum of a human ear) is N0. The noise signal NO in the target region may be acknowledged through collecting by another sensor near the target region, or may be derived by multiplying the external signal N1 collected by the first microphone 13 by a specific function, or, in some solutions, the external signal N1 collected by the first microphone 13 is used to equivalently replace NO. A characteristic function of electroacoustic conversion of the electroacoustic transducer is G(s).

Specifically, referring to FIG. 4, as an implementation of the fourth embodiment, the signal processing unit further includes a third signal processing circuit, the third signal processing circuit processes the electrical signals S3 and N3 that are processed by the first adder, a processed electrical signal is S4, the electrical signal S4 is transmitted to the electroacoustic transducer as the output signal of the signal processing unit, and the electroacoustic transducer is further configured to generate a noise reduction signal according to the received electrical signal.

The third signal processing circuit includes a fourth gain adjuster and a fourth filter that are electrically connected, a parameter of the fourth gain adjuster is Gain4, and a parameter of the fourth filter is Filter4.

The characteristic function of electroacoustic conversion of the electroacoustic transducer is G(s), and after the electrical signal S4 is received, the generated noise reduction signal is S4*G(s).

In order to achieve a noise reduction effect, it is necessary to satisfy

$$S {4}^{*} G ( s ) + N 0 = 0 ,$$

where

$$S 4 = {( S 3 + N 3 )}^{*} {Gain 4}^{*} Filter 4 , S 3 = 0 , and N 3 = N {1}^{*} {Gain 1}^{*} Filter 1 + N {2}^{*} {Gain 2}^{*} Filter 2 ,$$

so as to determine specific parameters of the parameter Gain4 of the fourth gain adjuster and the parameter Filter4 of the fourth filter. After the parameter Gain4 is determined, Filter4=−N0/((N3+S3)*Gain4)*G(s)).

Referring to FIG. 5, as an implementation of the fifth embodiment, the signal processing unit further includes a fourth signal processing circuit and a second adder, the fourth signal processing circuit is configured to process the electrical signal S1 and the electrical signal N1, a processed electrical signal is S5, the second adder is configured to process the electrical signal S3, the electrical signal N3, and the electrical signal S5, a processed electrical signal is S6, the electrical signal S6 is transmitted to the electroacoustic transducer as the output signal of the signal processing unit, and the electroacoustic transducer is further configured to generate a noise reduction electrical signal according to the received electrical signal.

The fourth signal processing circuit includes a third gain adjuster and a third filter that are electrically connected, a parameter of the third gain adjuster is Gain3, and a parameter of the third filter is Filter3.

The characteristic function of electroacoustic conversion of the electroacoustic transducer is G(s), and after the electrical signal S6 is received, the generated noise reduction signal is S6*G(s).

In order to achieve a noise reduction effect, it is necessary to satisfy

$$S {6}^{*} G ( s ) + N 0 = 0 , S {6}^{*} G ( s ) = - N 0 ,$$

where

$$S 6 = {( S 1 + N 1 )}^{*} Gain {3}^{*} Filter 3 + S 3 + N 3 ,$$

where

$$S 3 = 0 , N 3 = N {1}^{*} {Gain 1}^{*} Filter 1 + N {2}^{*} {Gain 2}^{*} Filter 2 ,$$

so as to determine specific parameters of the parameter Gain3 of the third gain adjuster and the parameter Filter3 of the fourth filter. After the parameter Gain3 is determined,

$$Filter 3 = ( - N 0 / G ( s ) - N 3 ) / {( S 1 + N 1 )}^{*} Gain 3 .$$

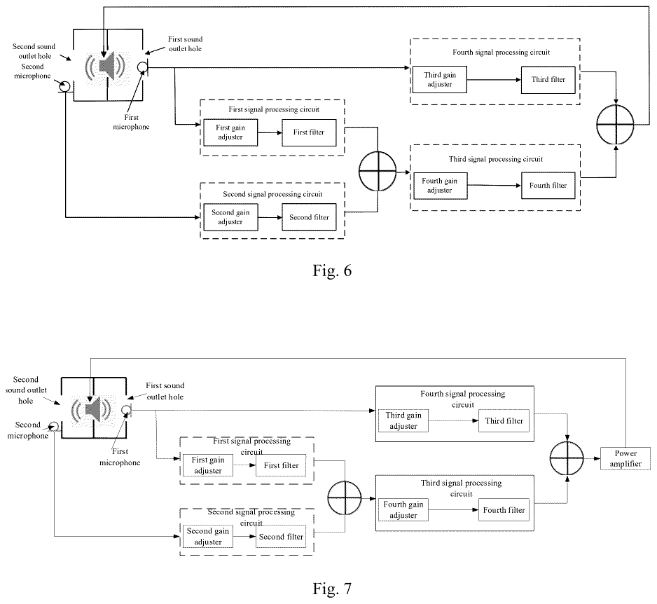

Referring to FIG. 6, as an implementation of the sixth embodiment, the signal processing unit further includes a third signal processing circuit, a fourth signal processing circuit, and a second adder, the fourth signal processing circuit is configured to process the electrical signal S1 and the electrical signal N1, a processed electrical signal is S7, the third signal processing circuit is configured to process the electrical signal S3 and the electrical signal N3, a processed electrical signal is S8, the second adder is configured to process the electrical signal S7 and the electrical signal S8, a processed electrical signal is S9, the electrical signal S9 is transmitted to the electroacoustic transducer as the output signal of the signal processing unit, and the electroacoustic transducer is further configured to generate a noise reduction sound signal according to the noise reduction electrical signal.

The third signal processing circuit includes a fourth gain adjuster and a fourth filter that are electrically connected, a parameter of the fourth gain adjuster is Gain4, and a parameter of the fourth filter is Filter4. The fourth signal processing circuit includes a third gain adjuster and a third filter that are electrically connected, a parameter of the third gain adjuster is Gain3, and a parameter of the third filter is Filter3.

The characteristic function of electroacoustic conversion of the electroacoustic transducer is G(s), and after the electrical signal S9 is received, the generated noise reduction signal is S9*G(s).

In order to achieve a noise reduction effect, it is necessary to satisfy

$$S {9}^{*} G ( s ) + N 0 = 0 , S {9}^{*} G ( s ) = - N 0 , where S 9 = S 7 + S 8 , S 7 = {( S 1 + N 1 )}^{*} {Gain 3}^{*} Filter 3 , and S 8 = {( S 3 + N 3 )}^{*} {Gain 4}^{*} Filter 4 .$$

It may be seen from the solutions of the fourth embodiment, the fifth embodiment, and the sixth embodiment that when the target noise signal NO is the same, S4=S6=S9.

In the fourth embodiment,

$$S 4 = {( S 3 + N 3 )}^{*} {Gain 4}^{*} Filter 4 ;$$

In the fifth embodiment,

$$S 6 = {( S 1 + N 1 )}^{*} {Gain 3}^{*} Filter 3 + S 3 + N 3 ;$$

In the sixth embodiment,

$$S 9 = {( S 1 + N 1 )}^{*} {Gain 3}^{*} Filter 3 + {( S 3 + N 3 )}^{*} {Gain 4}^{*} Filter 4 .$$

It may be seen that in the solution of the sixth embodiment, Gain4 and Filter4 are different from the parameters in the fourth embodiment, and Gain3 and Filter3 are different from the parameters in the fifth embodiment, that is, the electrical signal S7 is not equivalent to S5, and the electrical signal S8 is not equivalent to S4. In the sixth embodiment, the parameters Gain4, Filter4, Gain3, and Filter3 need to be reset to achieve the purpose of eliminating the target noise signal NO.

The noise reduction solution of the fourth embodiment is partially the same as the existing feedforward noise reduction solution, the noise reduction solution of the fifth embodiment is partially the same as the existing feedback noise reduction solution, and the sixth embodiment is partially the same as the existing hybrid noise reduction solution including feedforward noise reduction and feedback noise reduction. However, due to the structure of the noise reduction earphone of the present solution, which is equivalent to having two electroacoustic transducers, and the second microphone 14 receives the sound signal of the electroacoustic transducer, the difficulty in noise reduction processing is greater than that of the existing noise reduction technology. However, after the anti-howling solution of the first embodiment is combined with the above three embodiments, the noise reduction problem of the open earphone may be solved, and the problem that howling is easily generated in the existing noise reduction process may also be solved. It should be noted that the noise reduction effect of the sixth embodiment is better than that of the fourth embodiment or the fifth embodiment.

Referring to FIG. 7, based on the first embodiment shown in FIG. 1 to FIG. 3 and the fourth, fifth, and sixth embodiments shown in FIG. 4 to FIG. 6, a further solution of the present disclosure is provided. In the present solution, the noise reduction earphone further includes a power amplifier, which is configured to amplify the output signal of the signal processing unit before the output signal is transmitted to the electroacoustic transducer. An amplification factor of the power amplifier is K, and in the fourth embodiment,

$$S {4}^{*} {G ( s )}^{*} K + N 0 = 0 ;$$

In the fifth embodiment,

$$S {6}^{*} {G ( s )}^{*} K + N 0 = 0 ;$$

and in the sixth embodiment,

$$S {9}^{*} {G ( s )}^{*} K + N 0 = 0.$$

In different embodiments, a value of K may be changed according to requirements, where K may be greater than 1 or less than 1.

After obtaining the output signal of the signal processing unit according to the noise reduction system, the electroacoustic transducer generates the noise reduction signal according to the output signal, and generates noise reduction sound according to the noise reduction signal to cancel the noise in the target region.

In addition, further, the noise reduction earphone may be configured as an ear-hung earphone, and the noise reduction earphone structurally includes an ear hook and a battery portion, one end of the ear hook is connected to the sound emitting apparatus 10, and the other end of the ear hook is connected to the battery portion, and the ear hook is used to fix the noise reduction earphone on the ear of the user. The battery portion is configured to supply power to the sound emitting apparatus 10.

In order to achieve a better noise reduction effect, a first tuning hole is arranged in the first cavity or a sound short circuit tube is arranged between the first cavity and the second cavity. For an active noise reduction system including feedback noise reduction, a transfer function from the electroacoustic transducer to the first microphone 13 in the audio apparatus may be changed to some extent due to a wearing factor of the user, for example, when the radiation acoustic impedance at the first sound outlet hole 11 is different due to wearing as described above. In the present case, the first tuning hole is arranged in the first cavity, or the sound short circuit tube is arranged between the first cavity and the second cavity (the sound short circuit tube is not marked in the drawings), and the position of the first tuning hole and the sound short circuit tube will not be blocked by wearing; due to the existence of the first tuning hole or the sound short circuit tube, the radiation impedance in front of the diaphragm of the electroacoustic transducer is jointly constituted by the first sound outlet hole 11 and the first tuning hole 15 or the first sound outlet hole 11 and the sound short circuit. When the first sound outlet hole 11 is blocked, the change in radiation impedance is small due to the existence of the first tuning hole 15 or the sound short circuit tube, so that the transfer function from the electroacoustic transducer to the first microphone 13 will not change much, thus avoiding the instability of the feedback system and avoiding howling.

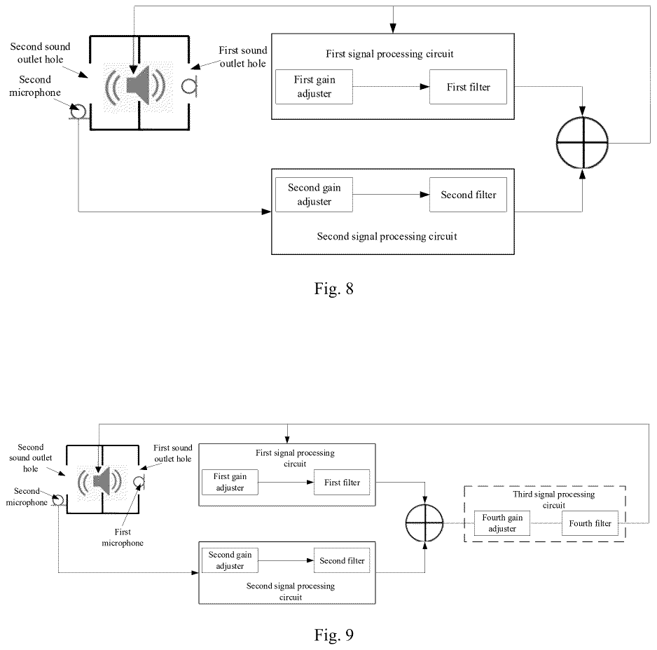

The seventh embodiment: the present disclosure provides another noise reduction earphone. Referring to FIG. 1 and FIG. 8, a preferred embodiment of the noise reduction earphone of the present disclosure includes a sound emitting apparatus 10, and the sound emitting apparatus 10 includes: a cavity, an electroacoustic transducer, a microphone, and a signal processing unit, the electroacoustic transducer is arranged in the cavity and divides the cavity into a first cavity and a second cavity, a first sound outlet hole 11 is arranged in the first cavity, and a second sound outlet hole 12 is arranged in the second cavity.

The microphone is arranged close to the second sound outlet hole 12 and is configured to collect a sound signal of the electroacoustic transducer in the second cavity and convert the sound signal into an electrical signal A2.

The signal processing unit includes a first signal processing circuit, a second signal processing circuit, and a first adder, the second signal processing circuit is configured to perform signal processing on the electrical signal A2, and a processed electrical signal is A12; the first signal processing circuit is configured to acquire an electrical signal A before being transmitted to the electroacoustic transducer and process the electrical signal A into an electrical signal A11; the electrical signal A11 and the electrical signal A12 have equal amplitudes and opposite phases; and the first adder is configured to process the electrical signal A11 and the electrical signal A12, a processed electrical signal is A3, the electrical signal A3 is transmitted to the electroacoustic transducer as an output signal of the signal processing unit, and an amplitude of the electrical signal A3 is zero.

The first signal processing circuit includes a first gain adjuster and a first filter that are electrically connected, and the second signal processing circuit includes a second gain adjuster and a second filter that are electrically connected. A parameter of the first gain adjuster is Gain1, a parameter of the first filter is Filter1, a parameter of the second gain adjuster is Gain2, a parameter of the second filter is Filter2, the electrical signal

$$A 11 = {A}^{*} {Gain 1}^{*} Filter 1 ,$$

the electrical signal

$$A 12 = A {2}^{*} {Gain 2}^{*} Filter 2 ,$$

and the electrical signal A3 satisfies:

$$A 3 = {A}^{*} {Gain 1}^{*} Filter 1 + S {2}^{*} {Gain 2}^{*} Filter 2 = 0 .$$

The difference between the seventh embodiment and the first embodiment lies in that in the present solution, the first microphone 13 in the first embodiment may be omitted, and the process of collecting the sound of the first sound outlet hole 11 by the first microphone 13 and converting the collected sound into an electrical signal may be omitted, and the first signal processing circuit directly acquires the electrical signal A from a circuit before the electrical signal is transmitted to the electroacoustic transducer. Compared with the first embodiment, the implementation of the present solution is simpler, and the occurrence of howling in the noise reduction system may also be avoided.

Referring to FIG. 9, a further technical solution of the present disclosure is that the microphone is further configured to collect an external sound signal and convert the external sound signal into an electrical signal B2, the second signal processing circuit is further configured to process the electrical signal B2, a processed electrical signal is B12, the first adder is configured to process the electrical signal B12 and the electrical signal A3, a processed electrical signal is B3, and the electrical signal B3 is transmitted to the electroacoustic transducer as the output signal of the signal processing unit, where

$$B 12 = B {2}^{*} {Gain 2}^{*} Filter 2 ,$$

and

$$B 3 = B 12 + A 3 = B 12 .$$

A noise signal in a target region (a space within a range from the first sound outlet hole 11 to an eardrum of a human ear) is N0, and a characteristic function of electroacoustic conversion of the electroacoustic transducer is G(s).

A technical solution of the eighth embodiment is that the signal processing unit further includes a third signal processing circuit, the third signal processing circuit processes the electrical signals A3 and B3 that are processed by the first adder, a processed electrical signal is A4, the electrical signal A4 is transmitted to the electroacoustic transducer as the output signal of the signal processing unit, and the electroacoustic transducer is further configured to generate a noise reduction electrical signal according to the received electrical signal.

The third signal processing circuit includes a third signal processing circuit, which includes a fourth gain adjuster and a fourth filter that are electrically connected, a parameter of the fourth gain adjuster is Gain4, and a parameter of the fourth filter is Filter4.

In order to achieve a noise reduction effect, it is necessary to satisfy

$$A {4}^{*} G ( s ) + N 0 = 0 ,$$

where

$$A 4 = {( A 3 + B 3 )}^{*} {Gain 4}^{*} Filter 4 ,$$

where

$$A 3 = 0 ,$$

and

$$B 3 = B {2}^{*} {Gain 2}^{*} Filter 2 ,$$

so as to determine specific parameters of the parameter Gain4 of the fourth gain adjuster and the parameter Filter4 of the fourth filter.

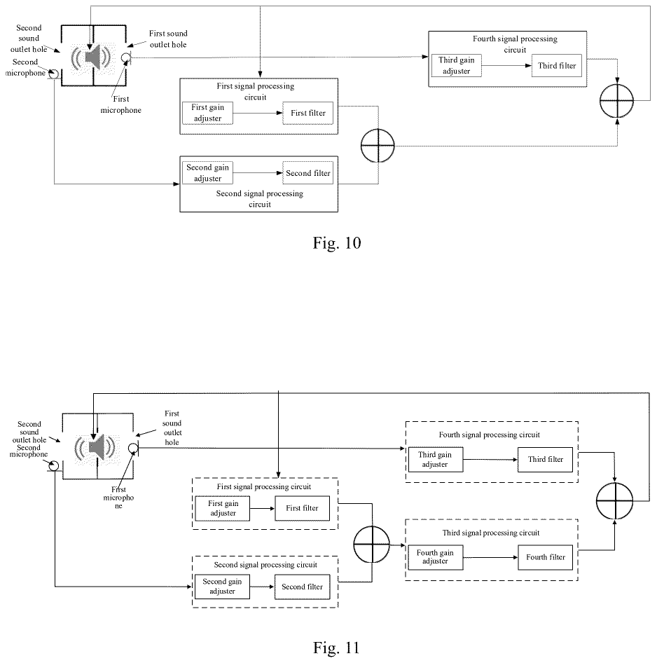

Referring to FIG. 10, a technical solution of the ninth embodiment is that the noise reduction earphone further includes another microphone, where the microphone arranged close to the second sound outlet hole 12 is the second microphone 14, and the microphone arranged in the first cavity is the first microphone 13; the first microphone 13 is configured to collect a sound signal of the electroacoustic transducer in the first cavity and convert the sound signal into an electrical signal A1 and an external sound signal B1, the second microphone 14 is further configured to collect an external sound signal and convert the external sound signal into an electrical signal B2, and the second signal processing circuit is further configured to process the electrical signal B2, a processed electrical signal is B12; and the signal processing unit further includes a fourth signal processing circuit and a second adder, the fourth signal processing circuit is configured to process the electrical signal A1 and the electrical signal B1, a processed electrical signal is A5, the second adder is configured to process the electrical signal B3, the electrical signal A3, and the electrical signal A5, a processed electrical signal is A6, the electrical signal A6 is transmitted to the electroacoustic transducer as the output signal of the signal processing unit, and the electroacoustic transducer is further configured to generate a noise reduction electrical signal according to the received electrical signal.

The fourth signal processing circuit includes a third gain adjuster and a third filter that are electrically connected, a parameter of the third gain adjuster is Gain3, and a parameter of the third filter is Filter3.

The characteristic function of electroacoustic conversion of the electroacoustic transducer is G(s), and after the electrical signal A6 is received, the generated noise reduction signal is A6*G(s).

In order to achieve a noise reduction effect, it is necessary to satisfy

$$A {6}^{*} G ( s ) + N 0 = 0 , A {6}^{*} G ( s ) = - N 0 ,$$

where

$$A 6 = {( B 1 + A 1 )}^{*} {Gain 3}^{*} Filter 3 + A 3 + B 3 ,$$

where

$$A 3 = 0 , B 3 = B {2}^{*} {Gain 2}^{*} Filter 2 ,$$

so as to determine specific parameters of the parameter Gain3 of the third gain adjuster and the parameter Filter3 of the fourth filter.

Referring to FIG. 11, a technical solution of the tenth embodiment is that the signal processing unit further includes a third signal processing circuit, a fourth signal processing circuit, and a second adder, the fourth signal processing circuit is configured to process the electrical signal S1 and the electrical signal N1, a processed electrical signal is A7, the third signal processing circuit is configured to process the electrical signal A3 and the electrical signal B3, a processed electrical signal is A8, the second adder is configured to process the electrical signal A7 and the electrical signal A8, a processed electrical signal is A9, the electrical signal A9 is transmitted to the electroacoustic transducer as the output signal of the signal processing unit, and the electroacoustic transducer is further configured to generate a noise reduction electrical signal according to the received electrical signal.

The third signal processing circuit includes a fourth gain adjuster and a fourth filter that are electrically connected, a parameter of the fourth gain adjuster is Gain4, and a parameter of the fourth filter is Filter4. The fourth signal processing circuit includes a third gain adjuster and a third filter that are electrically connected, a parameter of the third gain adjuster is Gain3, and a parameter of the third filter is Filter3.

The characteristic function of electroacoustic conversion of the electroacoustic transducer is G(s), and after the electrical signal A9 is received, the generated noise reduction signal is A9*G(s).

In order to achieve a noise reduction effect, it is necessary to satisfy

$$A {9}^{*} G ( s ) + N 0 = 0 , A {9}^{*} G ( s ) = - N 0 ,$$

where

$$A 9 = A 7 + A 8 , A 7 = {( A 1 + B 1 )}^{*} {Gain 3}^{*} Filter 3 ,$$

and

$$A 8 = {( A 3 + B 3 )}^{*} {Gain 4}^{*} Filter 4 .$$

It may be seen from the solutions of the eighth embodiment, the ninth embodiment, and the tenth embodiment that when the target noise signal N0 is the same,

$$A 4 = A 6 = A 9 .$$

In the fourth embodiment,

$$A 4 = {( A 3 + B 3 )}^{*} {Gain 4}^{*} Filter 4 ;$$

In the fifth embodiment,

$$A 6 = {( B 1 + A 1 )}^{*} {Gain 3}^{*} Filter 3 + A 3 + B 3 ;$$

In the sixth embodiment,

$$A 9 = {( A 1 + B 1 )}^{*} {Gain 3}^{*} Filter 3 + {( A 3 + B 3 )}^{*} {Gain 4}^{*} Filter 4 .$$

It may be seen that in the solution of the sixth embodiment, Gain4 and Filter4 are different from the parameters in the fourth embodiment, and Gain3 and Filter3 are different from the parameters in the fifth embodiment, that is, the electrical signal A7 is not equivalent to A5, and the electrical signal A8 is not equivalent to A4. In the sixth embodiment, the parameters of Gain4, Filter4, Gain3, and Filter3 need to be reset to achieve the purpose of eliminating the target noise signal N0.

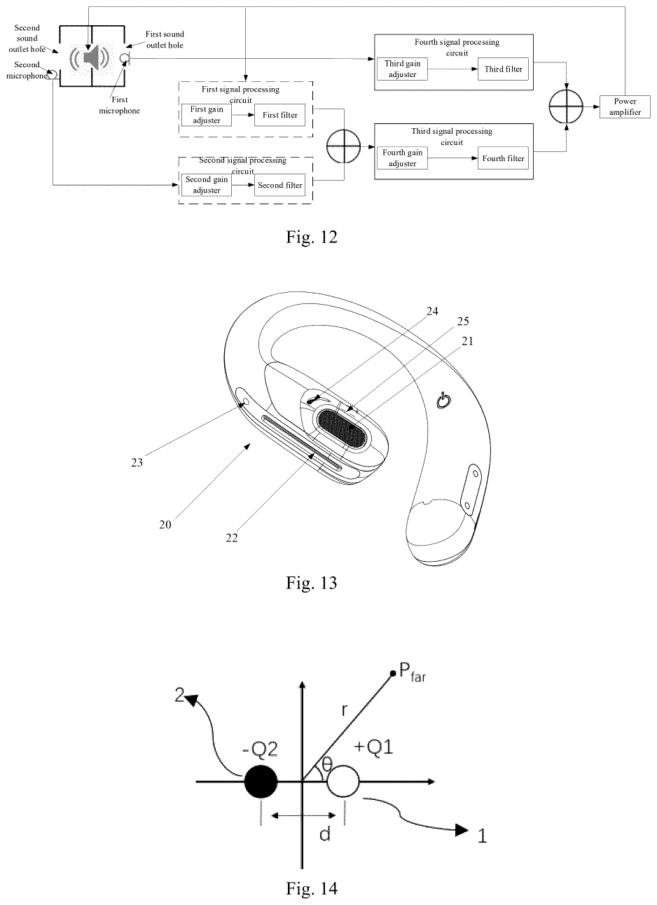

Referring to FIG. 12, a further technical solution of the present disclosure is that the noise reduction earphone further includes a power amplifier, which is configured to amplify the output signal of the signal processing unit before the output signal is transmitted to the electroacoustic transducer. In the eighth embodiment,

$$A {4}^{*} {G ( s )}^{*} K + N 0 = 0 ;$$

in the ninth embodiment,

$$A {6}^{*} {G ( s )}^{*} K + N 0 = 0 ;$$

and in the tenth embodiment,

$$A {9}^{*} {G ( s )}^{*} K + N 0 = 0.$$

In different embodiments, a value of K may be changed according to requirements, where K may be greater than 1 or less than 1.

In order to achieve the above object, the present disclosure provides another noise reduction earphone. Referring to FIG. 13, the eleventh embodiment: a first embodiment of another noise reduction earphone of the present disclosure includes a sound emitting apparatus 20, the sound emitting apparatus 20 includes a cavity, an electroacoustic transducer is arranged in the cavity, the electroacoustic transducer divides the cavity into a first cavity and a second cavity, a first sound outlet hole 21 is arranged in the first cavity, and a second sound outlet hole 22 is arranged in the second cavity. Specifically, the electroacoustic transducer may be an electroacoustic transducer, and a diaphragm is arranged on the electroacoustic transducer, and the diaphragm vibrates back and forth to squeeze air in the first cavity and the second cavity to generate sounds, which are propagated through the first sound outlet hole 21 of the first cavity and the second sound outlet hole 22 of the second cavity, respectively. Due to the structure of the noise reduction earphone, when the diaphragm vibrates, sounds propagated out through the first sound outlet hole 21 and the second sound outlet hole 22 have substantially the same amplitude and substantially opposite phases. The reason why the two groups of sounds do not have completely the same amplitude and completely opposite phases is that there is a difference in acoustic resistance between the front and rear of the diaphragm of the electroacoustic transducer. A first microphone 25 is arranged between the first sound outlet hole 21 and the electroacoustic transducer, a second microphone 23 is arranged on the sound emitting apparatus 20, the second microphone 23 is arranged close to the second sound outlet hole 22, and a first tuning hole 24 is arranged in the first cavity. For an active noise reduction system including feedback noise reduction, a transfer function from the electroacoustic transducer to the first microphone 25 in the audio apparatus may be changed to some extent due to a wearing factor of the user, for example, when the radiation acoustic impedance at the first sound outlet hole 21 is different due to wearing as described above. In the present case, the first tuning hole 24 is arranged in the first cavity, and the position of the first tuning hole 24 will not be blocked by wearing. Due to the existence of the first tuning hole 24, the radiation impedance in front of the diaphragm of the electroacoustic transducer is jointly constituted by the first sound outlet hole 21 and the first tuning hole 24. When the first sound outlet hole 21 is blocked, the change in radiation impedance is small due to the existence of the first tuning hole 24, so that the transfer function from the electroacoustic transducer to the first microphone 25 will not change much, thus avoiding the instability of the feedback system and avoiding howling.

Further, a center distance between the first sound outlet hole 21 and the first tuning hole 24 is not greater than 6 mm, and a distance between a center of the second sound outlet hole 22 and the center of the first sound outlet hole 21 is not greater than 15 mm. The first sound outlet hole 21 and the second sound outlet hole 22 constitute a pair of dipole sound sources, and the first tuning hole 24 and the second sound outlet hole 22 constitute a pair of dipole sound sources, and the two pairs of dipole sound sources approximately form a quadrupole sound source in space.

Referring to FIG. 14, in the existing open audio apparatus, a dipole sound source is formed before and after a diaphragm of an electroacoustic transducer unit or by driving two independent diaphragms to eliminate sound to prevent sound leakage, however, compared with a multipole sound source (such as a quadrupole sound source), the dipole sound source cannot achieve the effect of preventing sound leakage of the multipole sound source, and has the problems of disturbing others or having poor privacy, affecting the user experience.

The principle of forming a multipole by dipoles is as follows: the multipole sound source may be regarded as a combination of dipole sound sources with opposite polarities. A dipole sound source and a transverse quadrupole sound source are shown in FIG. 14. The dipole sound source is composed of a point sound source 1 (+Q1) and a sound source 2 (−Q2) as shown in the figure. The point sound source 1 and the point sound source 2 have the same amplitude and opposite phases, and a distance between the point sound source 1 and the point sound source 2 is d. An expression of sound pressure p at a distance r from the dipole sound source in the sound field is as shown in Equation 1.

$$\vert p ( r , θ , t ) \vert = \frac{Qpck}{4 π r} kd cos θ \qquad Equation ( 1 )$$

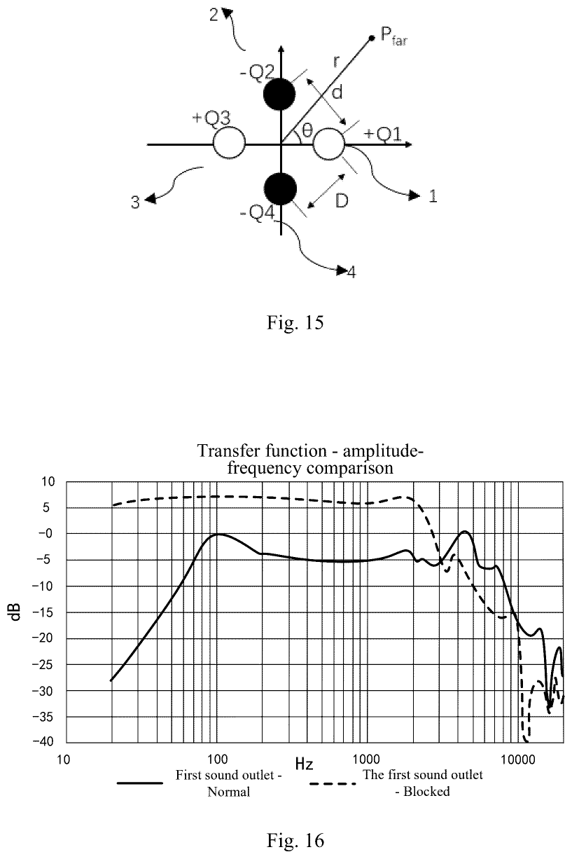

The quadrupole sound source is composed of two dipole sound sources with opposite phases. Referring to FIG. 15, the point sound source 1 (+Q1) and the point sound source 2 (−Q2) have the same amplitude and opposite phases, and a distance between the point sound source 1 and the point sound source 2 is d, to form a first dipole sound source; a point sound source 3 (+Q4) and a point sound source 4 (−Q4) have the same amplitude and opposite phases, and a distance between the point sound source 3 and the point sound source 4 is d, to form a second dipole sound source; the first dipole sound source and the second dipole sound source have opposite phases, and a distance between the first dipole sound source and the second dipole sound source is D. With the spatial layout shown in FIG. 15, a transverse quadrupole sound source is formed, and the sound pressure p at a distance r from the transverse quadrupole sound source is as shown in Equation 2.

$$\vert p ( r , θ , t ) \vert = \frac{Qpck}{4 π r} 4 {k}^{2} dD cos θ sin θ \qquad Equation ( 2 )$$

In the above expressions 1 and 2:
C—sound velocity
ρ—medium density
r—distance from a certain position in the sound field to the sound source
d—distance between dipole sound sources
D—distance between two dipole sound sources
Q—surface volume velocity of the sound source
k—wave node, k=2*π/λ
θ—sound source radiation angle.

By comparing the expressions 1 and 2, there is a ratio between the quadrupole sound source and the dipole sound source as shown in Equation 3:

$$4 kD sin θ \qquad Equation ( 3 )$$

When the distance between the two pairs of dipoles is relatively small, it satisfies

$$4 kD sin θ < 1$$

In the case where the amplitudes of the point sound sources are completely the same, the sound pressure radiated by the quadrupole sound source is smaller than that of the dipole sound source, therefore, it may be seen that the sound leaking outwards from the quadrupole sound source and the dipole sound source is smaller.

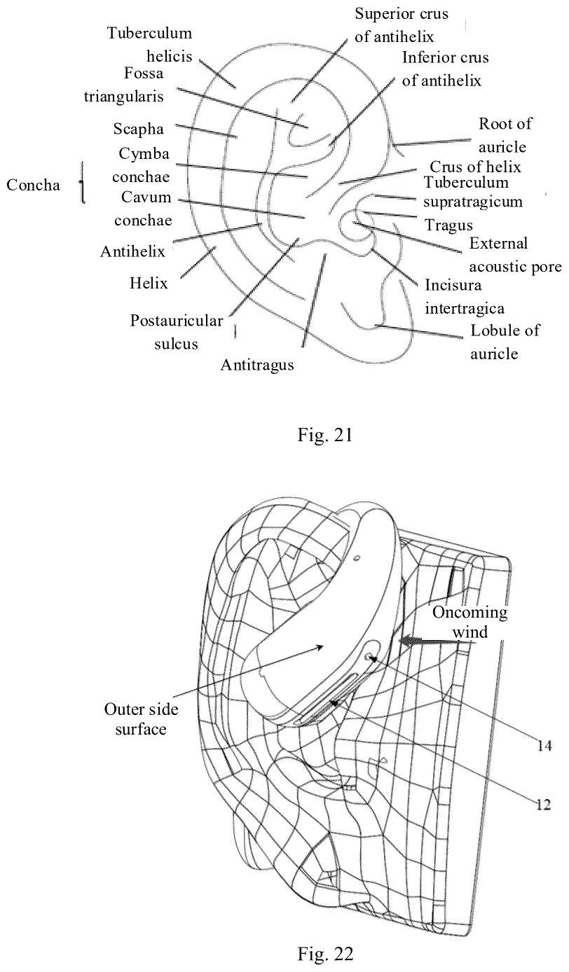

In the present solution, the center of the first sound outlet hole 21 is closer to the external auditory meatus than the center of the first tuning hole 24, the distance between the center of the first sound outlet hole 21 and the external auditory meatus does not exceed 13 mm, and the center distance between the first sound outlet hole 21 and the first tuning hole 24 is not greater than 6 mm. The distance between the center of the second sound outlet hole 22 and the center of the first sound outlet hole 21 is not greater than 15 mm; compared with the first sound outlet hole 21, the second sound outlet hole 22 has a larger distance from the external auditory meatus (referring to FIG. 21), and the center distance is not greater than 20 mm.

Due to the directivity of the dipole sound source or the quadrupole sound source in the far sound field, a certain position in the far sound field located on the line connecting the sound sources has a larger sound pressure level than other positions, such as the angle θ shown in Equation (2). Therefore, the second sound outlet hole 22 may be arranged on the side surface of the sound emitting portion to prevent the maximum sound leakage in the far sound field from being located in front of or on the side of the user. In some implementations, the second sound outlet hole 22 is located on the upper side surface or the lower side surface of the sound emitting portion, so that the angle formed by the line connecting the center of the second sound outlet hole 22 and the center of the first sound outlet hole 21 and a median plane of the human body is not greater than 80°, and the angle formed by the line connecting the center of the second sound outlet hole 22 and the center of the first tuning hole 24 and the median plane of the human body is not greater than 70°.

The comparison results shown in FIG. 16 show that when the sound emitting apparatus 20 is not provided with the first tuning hole 24, the change in amplitude-frequency response is very large after the first sound outlet hole 21 is completely blocked when compared with the normal operation of the first sound outlet hole 21, for example, about 10 dB in the middle and high frequency part and more than 10 dB in the low frequency part, which increases the difficulty in designing the feedback filter, and the noise reduction performance is greatly sacrificed in order to ensure the stability of the active noise reduction system without howling.

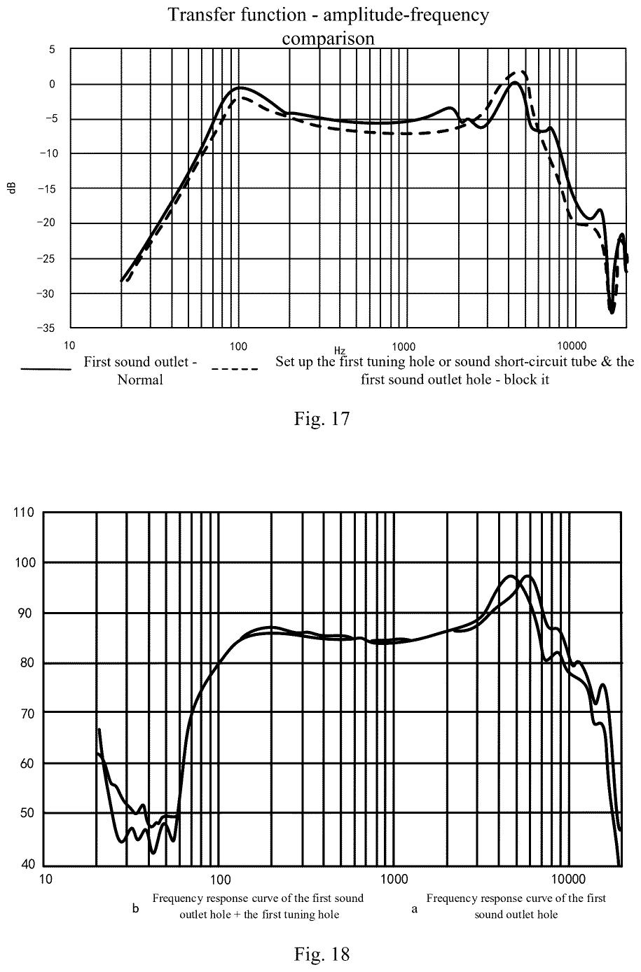

As shown in the comparison results shown in FIG. 17, when the first tuning hole 24 is arranged in the sound emitting apparatus 20, the change in amplitude-frequency response is smaller after the first sound outlet hole 21 is completely blocked when compared with the normal operation of the first sound outlet hole 21, and the change is controlled within 3 dB, which is beneficial to the design of the noise reduction filter and increasing the active noise reduction performance.

The influence of the position of the first tuning hole 24 on the high-frequency frequency response curve is described below.

It may be seen from the basic acoustic principles that when an incident sound wave and a reflected sound wave exist in a space and the wavelength of the sound wave is comparable to the size of the space, the incident sound wave and the reflected sound wave form a standing wave, thereby forming a node and an antinode. Because the wavelength of a high-frequency sound wave is short, the node and the antinode usually occur at a high frequency, thus affecting the high-frequency sound quality. In the present embodiment, it is preferentially to design the inner side cavity surfaces of the front and rear cavities of the diaphragm of the electroacoustic transducer as arc structures, however, there are still approximately parallel surfaces and surfaces approximately parallel to the diaphragm of the electroacoustic transducer, thus providing conditions for the formation of the standing wave. Taking the maximum distance from the center of the first sound outlet hole 21 to the inner side surface of the first cavity as Xk, when Xk satisfies the following formula, an antinode, that is, a maximum value of the sound, is formed at the first sound outlet hole 21, and a peak is generated on the frequency response curve.

$${X}_{k} = ( 2 k + 1 ) \frac{λ}{4} = \frac{k λ}{2} + \frac{λ}{4} \qquad ( 4 )$$

$${f}_{0} = \frac{{c}_{0}}{4 L} ( 2 n - 1 ) \qquad ( 5 )$$

where f0 is the frequency of the antinode of the standing wave, that is, the frequency corresponding to the peak on the frequency response curve, c0 is the speed of sound propagation in the air, and L is the maximum spacing from the center of the first sound outlet hole 21 to the inner side surface of the first cavity.

Another case where a peak and a trough are generated is that resonance is formed between the first front cavity and the first sound outlet hole 21, thereby generating a peak, and the resonance frequency formula is:

$${f}_{0} = \frac{{c}_{0}}{2 π} \sqrt{\frac{S}{V ( l + 1.7 r )}} \qquad ( 6 )$$

where f0 is the resonance frequency of the first cavity and the first sound outlet hole 21, c0 is the propagation speed of sound waves in the air, S is the actual area of the first sound outlet hole 21, V is the actual volume of the first cavity, l is the length of the first sound outlet hole 21, and r is the equivalent radius of the first sound outlet hole 21.

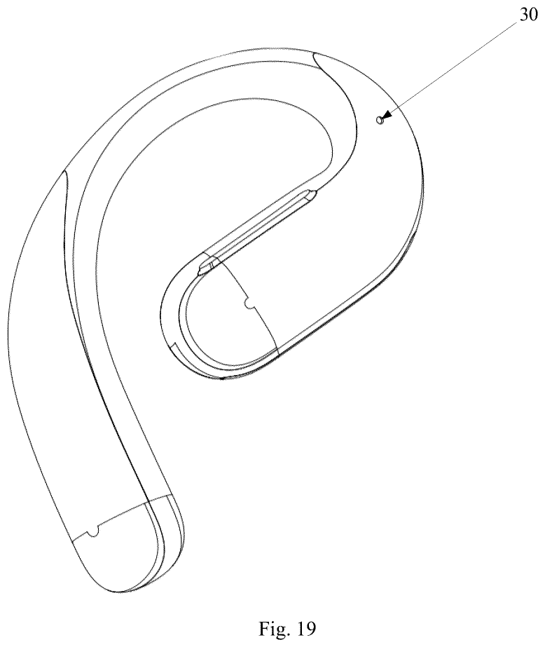

In the present embodiment, the resonance frequency formed by the first cavity and the first sound outlet hole 21 is as shown by the curve a in FIG. 18, which is close to 5 KHz, however, a trough is formed close to 8 KHz. It may be seen that the first cavity and the first sound outlet hole 21 form a peak and also form a trough. In order to improve the bandwidth and ductility of the earphone in the high frequency, it is necessary to move the resonance frequency of the peak to a higher frequency and increase the sound pressure level of the frequency response curve in the trough region. In the present embodiment, the first tuning hole 24 is designed on the surface of the first cavity, and the area of the sound outlet hole on the first cavity may be equivalently increased through the first tuning hole 24. It may be seen from Equation 6 that the resonance frequency moves to a high frequency, as shown by the curve b in FIG. 18, the resonance frequency of the peak has been adjusted to be close to 6 KHz. On the other hand, the standing wave effect of the position of the first tuning hole 24 is utilized to make the frequency of the standing wave close to the frequency of the aforementioned trough, thereby increasing the frequency response curve of this frequency band and increasing the bandwidth and ductility, specifically as shown by the curve b in FIG. 18, the frequency response curve close to 8 KHz is further increased, about 7 dB. According to Equation 5, in order to improve the frequency response of the frequency band near 8 KHz, the maximum distance from the center of the first tuning hole 24 to the inner cavity surface of the first cavity is between 9 mm and 13 mm. In some implementations, in the present embodiment, the maximum distance from the center of the first tuning hole 24 to the inner cavity side surface of the first cavity is 11 mm, and the frequency of the antinode of the standing wave is 8000 Hz, thereby improving the trough formed by the first tuning hole 24 and the first cavity.

In the present embodiment, although the standing wave is utilized to increase the frequency response curve and the high-frequency sound quality performance of the earphone, in order to minimize other influences caused by the standing wave, the inner cavity surface of the first cavity includes inner side surfaces opposite to each other, and the surfaces perpendicular to the vibration direction of the diaphragm of the electroacoustic transducer are designed as arc surfaces, thereby minimizing the energy and probability of the generation of the standing wave. In the present embodiment, the inner cavity surfaces of the first cavity located on both sides of the long axis direction of the electroacoustic transducer are arc surfaces, and in addition, the inner cavity surfaces are opposite inclined surfaces, which changes the incident angle of the sound wave to some extent and reduces the generation of the standing wave.

It is worth mentioning that when the earphone is worn on the human ear, the sound emitting portion of the earphone covers part of the concha, the crus of helix and the cymba conchae, and from an ergonomic perspective, the covered area may be slightly different when different people wear the earphone. In order to enable the first sound outlet hole 21 of the earphone close to the external auditory meatus when worn by different people, the first sound outlet hole 21 should cover the external auditory meatus, the incisura terminalis, the cymba conchae, and the crus of helix (referring to FIG. 21). In some implementations, the first sound outlet hole 21 has a larger dimension along the length direction of the sound emitting portion than along the height direction of the sound emitting portion, such as the long side of a runway shape, the long side of a rectangle, the long axis of an ellipse, or the like. The ratio of the dimension of the first sound outlet hole 21 along the length direction of the sound emitting portion to the dimension of the first sound outlet hole 21 along the height direction of the sound emitting portion is between 1.1 and 3.5.

In order to reduce the standing wave in the second cavity (rear cavity), the inner side cavity surface of the second cavity is designed as a circular arc surface or an opposite inclined surface relative to the side surface. In some implementations, there is an arc along the width direction of the sound emitting portion, and the earphone is provided with a partition plate, and the partition plate is made of stainless steel. The stainless steel is parallel to the bottom of the electroacoustic transducer. In order to reduce the generation of the standing wave, the distance between the stainless steel spacer and the bottom of the electroacoustic transducer is adjusted to enable the surface spacing between the spacer and the bottom of the electroacoustic transducer is diverse, thereby reducing the generation of the standing wave. Optionally, the distance has at least two different size ratios. Because the second rear cavity and the second sound outlet hole 22 have a high-frequency resonance frequency, which also affects the frequency response curve of the earphone, in some implementations, the larger the opening area of the second sound outlet hole 22, the better. On the one hand, the high-frequency resonance frequency moves to a higher frequency, and on the other hand, the larger the second sound outlet hole 22, the easier it is for the air in the second cavity to be pushed by the diaphragm of the electroacoustic transducer, thereby generating better low frequency. The ratio of the area of the second sound outlet hole 22 to the area of the first sound outlet hole 21 is between 1 and 2. Considering the appearance of the product, the second sound outlet hole 22 has a larger dimension than the first sound outlet hole 21 in the length direction of the sound emitting portion, and the size ratio is between 1.5 and 3.

In the present embodiment, the center distance between the sound pickup hole of the second microphone 23 and the second sound outlet hole 22 is not greater than 5 mm. In the design of a traditional noise reduction earphone, the sound pickup hole of the second microphone 23 is designed to be as far as possible from a sound outlet hole, that is, the microphone is designed to collect as little sound as possible emitted by the electroacoustic transducer and only collect external noise, and noise reduction design is performed based on this idea. In particular, the second microphone 23 is basically designed to be far away from the second sound outlet hole 22, and even in many noise reduction earphones, the second microphone 23 is designed at an acoustic zero position of an acoustic dipole radiation sound field formed by the first sound outlet hole 21 and the second sound outlet hole 22, so that the second microphone 23 cannot collect the sound emitted by the electroacoustic transducer at all. These designs lead to inaccurate noise determination of the noise reduction system and fail to achieve a better noise reduction effect, or these designs cause howling. The technical path of the present solution is different from that of the above solution. In the present solution, the first microphone 25 is arranged as close as possible to the first sound outlet hole 21 and the second microphone 23 is arranged as close as possible to the second sound outlet hole 22, for example, a center distance between the sound pickup hole of the first microphone 25 and the first sound outlet hole 21 may be set to not greater than 5 mm according to an actual situation, and a center distance between the sound pickup hole of the second microphone 23 and the second sound outlet hole 22 may also be set to not greater than 5 mm according to an actual situation, so as to facilitate the collection of the sound of the first sound outlet hole 21 by the first microphone 25 and the collection of the sound of the second sound outlet hole 22 by the second microphone 23. As may be seen from the above solution, in the present embodiment, by arranging an anti-howling circuit, the sound signal collected by the first microphone 25 and the sound signal collected by the second microphone 23 are completely cancelled in the noise reduction system and are not transmitted back to the electroacoustic transducer. Compared with the solution of arranging the microphone away from the sound outlet hole, the present solution has better noise reduction and anti-howling effects.

A vertical distance from the sound pickup hole of the first microphone 25 to a straight line where the center points of the first sound outlet hole 21 and the first tuning hole 24 are located is not greater than 5 mm. The sound pickup hole of the first microphone 25 is close to the first sound outlet hole 21 and the first tuning hole 24, which facilitates the collection of the sound signal of the first sound outlet hole 21.

Further, when the first microphone 25 is used for active noise reduction, the first microphone 25 may further be used for communication, and cooperate with the circuit system of the noise reduction earphone to realize the call function. Due to the position of the first microphone 25, the first microphone may cooperate with the structural features such as the first sound outlet hole 21, the first tuning hole 24, and the first cavity to avoid of picking up external wind noise during the communication, thereby obtaining a good call effect.

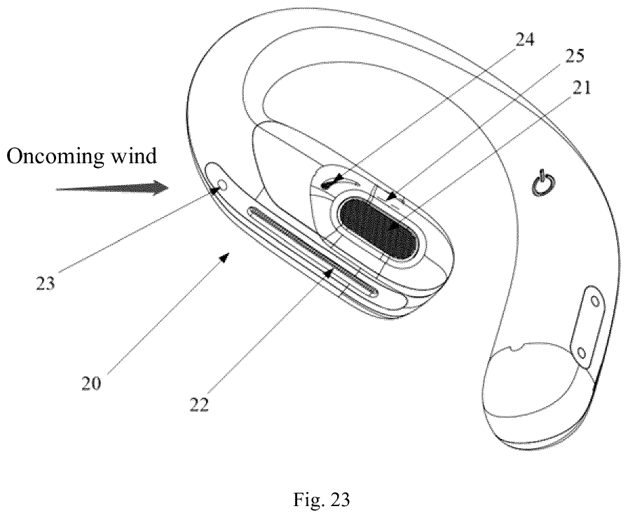

Referring to FIGS. 22 to 23, the scenario where the user is in an oncoming wind is specifically described. The oncoming wind blows on the face of the user from the front of the human body, and then blows on the ears or the earphone; or when the user is moving, the direction of the wind is opposite to the moving direction of the user. Specifically, as shown in FIG. 23, which is a schematic diagram of the noise reduction earphone worn on a right ear auricle model, and in order to more clearly show the first tuning hole 24, the first sound outlet hole 21, and the first microphone 25 on the noise reduction earphone, the right ear auricle model is not shown in FIG. 23. For the convenience of description, the oncoming wind direction shown in FIG. 23 is from left to right, which corresponds to the oncoming wind direction from the front of the human body to the back of the human body in an actual application scenario, so that the earphone is subjected to the oncoming wind.

Referring to FIG. 23, the oncoming wind direction is from left to right, and the oncoming wind first acts on the first tuning hole 24, and then acts on the first sound outlet hole 21. In the present design, the first sound outlet hole 21 and the first tuning hole 24 are provided with steel meshes, and acoustic mesh cloths are arranged under the steel meshes of the first sound outlet hole 21 and the first tuning hole 24. The first tuning hole 24 and the first sound outlet hole 21 are attached with the acoustic mesh cloths, and the steel meshes and the acoustic meshes may form a certain blocking effect on the wind, thereby reducing the wind noise energy acting on the first microphone 25.

Further, after the wind is blown into the front cavity through the first tuning hole 24, the wind may move in the front cavity to the first sound outlet hole 21 and is quickly blown out.

The first tuning hole 24, the first sound outlet hole 21, the mesh cloth attached to the first tuning hole 24, the mesh cloth of first sound outlet hole 21, the steel mesh, and the front cavity prevent the wind from directly acting on the first microphone 25 by dispersing the wind energy and diverting the wind energy, thereby reducing the wind noise. Further, in order to allow the wind energy to quickly dissipate from the first sound outlet hole 25, the shape of the first sound outlet hole 21 may be one of a rectangle, a runway shape, or an ellipse. When the first tuning hole 21 is rectangular or runway-shaped, the length of the long side of the first sound outlet hole 21 is 2 to 5 times the length of the short side of the first sound outlet hole 21; when the first tuning hole 21 is elliptical, the length of the long axis of the first sound outlet hole 21 is 2 to 5 times the length of the short axis of the first sound outlet hole 21. Referring to FIG. 23, the first sound outlet hole 21 has a larger dimension in the oncoming wind direction than in the direction perpendicular to the oncoming wind, and the dimension is designed such that the first sound outlet hole 21 has a larger dimension in the length direction of the sound emitting portion than in the height direction of the sound emitting portion on the earphone, and the ratio of the dimensions is between 2 times and 5 times.

Further, in order to prevent the wind energy entering the front cavity from acting on the first microphone 25, the sound pickup hole of the first microphone 25 is located beside the first sound outlet hole 21, and in some implementations, the sound pickup hole of the first microphone 25 is located on the long side of the first sound outlet hole, and the position of the sound pickup hole of the first microphone 25 avoids the opening interval between the first tuning hole 24 and the first sound outlet hole 21, so as to prevent the wind from flowing into the sound pickup hole of the first microphone 25 when the wind flows from the first tuning hole 24 to the first sound outlet hole 21.

In an actual application scenario, the noise reduction earphone is also subjected to winds from other directions, for example, the wind direction is perpendicular to the outer side surface of the human ear. Because the first microphone 25 is located in the front cavity close to the first sound outlet hole 21, the cavity may form a windbreak wall for the first microphone 25 to prevent the wind from directly acting on the sound pickup hole of the first microphone 25, which may effectively reduce the energy of the wind noise picked up by the first microphone 25, thereby increasing the call effect.

A further technical solution of the present disclosure is that the sound pickup hole of the first microphone 25 faces towards the diaphragm of the electroacoustic transducer. In some implementations, the sound pickup hole of the first microphone 25 is arranged to directly face towards the diaphragm of the electroacoustic transducer and away from the steel mesh of the first sound outlet hole 21, so as to prevent wind energy from acting on the diaphragm of the microphone, thereby further reducing the wind noise.

A further technical solution of the present disclosure is that the sound pickup hole of the first microphone 25 is located beside the first sound outlet hole 21, the distance between the sound pickup hole of the first microphone 25 and an edge of the first sound outlet hole 21 is between 3 mm and 5 mm, and the center distance between the sound pickup hole of the first microphone 25 and the first tuning hole 24 is greater than 5 mm.

A further technical solution of the present disclosure is that the first surface has an arc-shaped design. The arc-shaped design may be more favorable for a smooth outflow of wind speed and a change of wind direction when the wind acts on the earphone, thereby reducing the wind energy acting on the first tuning hole 24 and the first sound outlet hole 21. Further, the first surface is designed with a convex structure, the first sound outlet hole 21 is located on an end surface of the convex structure, the convex structure has a certain arc-shaped design from the first surface to the end surface, and the convex structure may also play a role in blocking wind and dispersing wind. An included angle between a plane where the end surface is located and a plane where the diaphragm of the electroacoustic transducer is located is between 30 degrees and 60 degrees.

Through the above specific embodiments, those skilled in the art may easily think of sub-optimal solutions, such as eliminating the first tuning hole based on the above solution, or adjusting a direction of the sound pickup hole of the first microphone 25 so that the sound pickup hole of the first microphone 25 is arranged to face away from the diaphragm of the electroacoustic transducer, the first microphone 25 is still arranged inside the front cavity, and the front cavity may provide a windbreak wall for the sound pickup hole of the first microphone 25, thereby reducing the wind noise energy picked up by the sound pickup hole of the first microphone 25. A further technical solution of the present disclosure is that, referring to FIG. 19, the noise reduction earphone further includes a third microphone, and the third microphone and the second microphone 23 cooperate with a directivity algorithm to form dual-microphone call noise reduction. The front microphone and the rear microphone are used for directional processing, and the sound signal obtained by the third microphone needs to be delayed to ensure that the sound signal and the rear signal received by the second microphone 23 reach at the same time. Then the signal of the third microphone is subtracted from the signal of the second microphone 23 to obtain the front sound signal, that is, to obtain the directivity effect.

A further technical solution of the present disclosure is that when a standard mannequin wears the noise reduction earphone, an included angle between a first straight line formed by the sound pickup hole of the second microphone 23 and a center point of a mouth and a second straight line formed by the sound pickup hole of the third microphone and the center point of the mouth is less than 30 degrees. In some implementations, in the wearing state of the noise reduction earphone, the sound pickup hole of the third microphone, the sound pickup hole of the second microphone 23, and the center point of the mouth of the user are on a straight line, or, a straight line where a connection line between the sound pickup hole of the third microphone and the sound pickup hole of the second microphone 23 is located is as close as possible to the center point of the mouth, so as to better pick up the voice of the user.

A further technical solution of the present disclosure is that the distance between the sound pickup hole of the third microphone and the sound pickup hole of the second microphone 23 is greater than 15 mm.

A further technical solution of the present disclosure is that the distances between the sound pickup hole of the second microphone 23 and the edges of the first sound outlet hole 21 and the first tuning hole 24 are both greater than 10 mm.

A further technical solution of the present disclosure is that a sound short circuit tube is arranged between the first cavity and the second cavity (the sound short circuit tube is not marked in the drawings). Arranging the sound short circuit tube between the first cavity and the second cavity may be an alternative solution to arranging the first tuning hole 24 or a supplementary solution after arranging the first tuning hole 24. As described above, by arranging the sound short circuit tube between the first cavity and the second cavity, the radiation impedance in front of the diaphragm of the electroacoustic transducer is jointly constituted by the first sound outlet hole 21 and the first tuning hole 24 or jointly constituted by the first sound outlet hole 21 and the sound short circuit. When the first sound outlet hole 21 is blocked, the change in radiation impedance is small due to the existence of the first tuning hole 24 or the sound short circuit tube, so that the transfer function from the electroacoustic transducer to the first microphone 25 will not change much, thus avoiding the instability of the feedback system and avoiding howling.

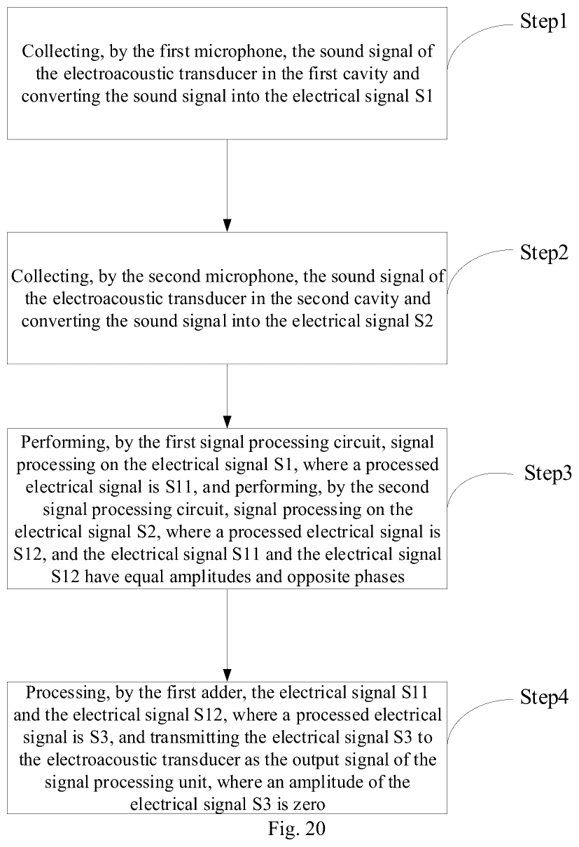

In order to achieve the above object, the present disclosure further provides a earphone noise reduction method, which is applied to a noise reduction earphone, where the noise reduction earphone includes an electroacoustic transducer, a first microphone 25, a second microphone 23, and a signal processing unit, the signal processing unit includes a first signal processing circuit, a second signal processing circuit, and a first adder, the first microphone 25 is configured to collect a sound signal of the electroacoustic transducer in a first cavity and convert the sound signal into an electrical signal S1, and the second microphone 23 is configured to collect a sound signal of the electroacoustic transducer in a second cavity and convert the sound signal into an electrical signal S2. Referring to FIG. 20, a first embodiment of the method includes the following steps:
Step 1: collecting, by the first microphone 25, the sound signal of the electroacoustic transducer in the first cavity and converting the sound signal into the electrical signal S1;
Step 2: collecting, by the second microphone 23, the sound signal of the electroacoustic transducer in the second cavity and converting the sound signal into the electrical signal S2;
Step 3: performing, by the first signal processing circuit, signal processing on the electrical signal S1, where a processed electrical signal is S11, and performing, by the second signal processing circuit, signal processing on the electrical signal S2, where a processed electrical signal is S12, and the electrical signal S11 and the electrical signal S12 have equal amplitudes and opposite phases; and
Step 4: processing, by the first adder, the electrical signal S11 and the electrical signal S12, where a processed electrical signal is S3, and transmitting the electrical signal S3 to the electroacoustic transducer as an output signal of the signal processing unit, where an amplitude of the electrical signal S3 is zero.

The first signal processing circuit includes a first gain adjuster and a first filter that are electrically connected, and the second signal processing circuit includes a second gain adjuster and a second filter that are electrically connected. A parameter of the first gain adjuster is Gain1, a parameter of the first filter is Filter1, a parameter of the second gain adjuster is Gain2, a parameter of the second filter is Filter2, the electrical signal

$$S 11 = S {1}^{*} {Gain 1}^{*} Filter 1 ,$$

the electrical signal

$$S 12 = S {2}^{*} {Gain 2}^{*} Filter 2 ,$$

and the electrical signal S3 satisfies:

$$S 3 = S {1}^{*} Gain {1}^{*} Filter 1 + S {2}^{*} {Gain 2}^{*} Filter 2 = 0 .$$

After the above condition is met, parameters of the first signal processing circuit and the second signal processing circuit are kept unchanged, and in the present embodiment, parameters of the first gain adjuster and the first filter, and parameters of the second gain adjuster and the second filter are kept unchanged, so that the electrical signal S3 satisfies the above condition.

In the present embodiment, the electrical signal S1 is processed by the first signal processing circuit to obtain the processed electrical signal S11, the electrical signal S2 is processed by the second signal processing circuit to obtain the processed electrical signal S12, the electrical signal S11 and the electrical signal S12 have equal amplitudes and opposite phases, and then the electrical signal S11 and the electrical signal S12 are processed by the first adder, so that a signal transmitted to the electroacoustic transducer is zero, thereby greatly increasing the active noise reduction performance of the earphone without generating howling, and providing a good immersive experience for a user when the user uses the open earphone but does not want to hear external sounds.

Based on the first embodiment proposed in FIG. 20, a second embodiment of the earphone noise reduction method of the present disclosure is provided. The difference between the present embodiment and the first embodiment shown in FIG. 13 lies in that the first microphone 25 is further configured to collect an external sound signal and convert the external sound signal into an electrical signal N1, and the second microphone 23 is further configured to collect an external sound signal and convert the external sound signal into an electrical signal N2;
Step 1 further includes: collecting, by the first microphone 25, the external sound signal and converting the external sound signal into the electrical signal N1;
Step 2 further includes: collecting, by the second microphone 23, the external sound signal and converting the external sound signal into the electrical signal N2;
Step 3 further includes: processing, by the first signal processing circuit, the electrical signal N1, where a processed electrical signal is N11, and processing, by the second signal processing circuit, the electrical signal N2, where a processed electrical signal is N12; and
Step 4 further includes: processing, by the first adder, the electrical signal N11 and the electrical signal N12, where a processed electrical signal is N3, and transmitting the electrical signal N3 to the electroacoustic transducer as the output signal of the signal processing unit.

Specifically, as an implementation, the signal processing circuit further includes a third signal processing circuit, and Step 4 further includes the following steps:
Step 5: processing, by the third signal processing circuit, the electrical signals S3 and N3 that are processed by the first adder, where a processed electrical signal is S4, and transmitting the electrical signal S4 to the electroacoustic transducer as the output signal of the signal processing unit; and
Step 6: generating, by the electroacoustic transducer, the noise reduction electrical signal according to the received electrical signal.

As another implementation, the signal processing unit further includes a fourth signal processing circuit and a second adder, and before Step 4, the method further includes the following step:
Step 41: processing, by the fourth signal processing circuit, the electrical signal S1 and the electrical signal N1, where a processed electrical signal is S5; and after Step 4, the method further includes the following steps:
Step 42: processing, by the second adder, the electrical signal S3, the electrical signal N3, and the electrical signal S5, where a processed electrical signal is S6, and transmitting the electrical signal S6 to the electroacoustic transducer as the output signal of the signal processing unit; and
Step 43: generating, by the electroacoustic transducer, a noise reduction signal according to the received electrical signal.

As yet another implementation, the signal processing unit further includes a third signal processing circuit, a fourth signal processing circuit, and a second adder, and before Step 4, the method further includes the following step:
Step 41: processing, by the fourth signal processing circuit, the electrical signal S1 and the electrical signal N1, where a processed electrical signal is S7; and
after Step 4, the method further includes the following steps:
Step 42: processing, by the third signal processing circuit, the electrical signal S3 and the electrical signal N3, where a processed electrical signal is S8;
Step 43: processing, by the second adder, the electrical signal S7 and the electrical signal S8, where a processed electrical signal is S9, and transmitting the electrical signal S9 to the electroacoustic transducer as the output signal of the signal processing unit; and
Step 44: generating, by the electroacoustic transducer, the noise reduction electrical signal according to the received electrical signal.

In the present embodiment, the noise reduction earphone may further include a power amplifier, and Step 43 further includes: amplifying the electrical signal S9 by the power amplifier.

Obviously, those skilled in the art may make various modifications and variations to the present disclosure without departing from the spirit and scope of the present disclosure. The present application is intended to cover these modifications and variations provided that they fall within the scope of the claims of the present disclosure and their equivalent technologies.

1. A noise reduction earphone, comprising a sound emitting apparatus, wherein the sound emitting apparatus comprises: a cavity, an electroacoustic transducer, a first microphone, a second microphone, and a signal processing unit;
the electroacoustic transducer is arranged in the cavity and divides the cavity into a first cavity and a second cavity, the first cavity is provided with a first sound outlet hole, and the second cavity is provided with a second sound outlet hole;
the first microphone is arranged in the first cavity and is configured to collect a sound signal of the electroacoustic transducer in the first cavity and convert the sound signal into a first electrical signal S1;
the second microphone is arranged close to the second sound outlet hole and is configured to collect a sound signal of the electroacoustic transducer in the second cavity and convert the sound signal into a second electrical signal S2; and
the signal processing unit comprises a first signal processing circuit, a second signal processing circuit, and a first adder, the first signal processing circuit is configured to perform signal processing on the first electrical signal S1, a first processed electrical signal is S11, the second signal processing circuit is configured to perform signal processing on the second electrical signal S2, a second processed electrical signal is S12, and the first processed electrical signal S11 and the second processed electrical signal S12 have equal amplitudes and opposite phases; and the first adder is configured to process the first processed electrical signal S11 and the second processed electrical signal S12, a third processed electrical signal is S3, the third processed electrical signal S3 is transmitted to the electroacoustic transducer as an output signal of the signal processing unit, and an amplitude of the third processed electrical signal S3 is zero.

2-3. (canceled)

4. The noise reduction earphone of claim 1, wherein the first microphone is further configured to collect an external sound signal and convert the external sound signal into a third electrical signal N1, and the second microphone is further configured to collect an external sound signal and convert the external sound signal into a fourth electrical signal N2; and the first signal processing circuit is further configured to process the third electrical signal N1, a fourth processed electrical signal is N11, the second signal processing circuit is further configured to process the fourth electrical signal N2, a fifth processed electrical signal is N12, the first adder is further configured to process the fourth processed electrical signal N11 and the fifth processed electrical signal N12, a sixth processed electrical signal is N3, and the sixth processed electrical signal N3 is transmitted to the electroacoustic transducer as the output signal of the signal processing unit.

5. The noise reduction earphone of claim 4, wherein the signal processing unit further comprises a third signal processing circuit, the third signal processing circuit processes the third processed electrical signal S3 and the sixth processed electrical signal N3 that are processed by the first adder, a seventh processed electrical signal is S4, the seventh processed electrical signal S4 is transmitted to the electroacoustic transducer as an output signal of the signal processing unit, and the electroacoustic transducer is further configured to generate a noise reduction electrical signal according to a received electrical signal.

6. The noise reduction earphone of claim 4, wherein the signal processing unit further comprises a fourth signal processing circuit and a second adder, the fourth signal processing circuit is configured to process the first electrical signal S1 and the third electrical signal N1, an eighth processed electrical signal is S5, the second adder is configured to process the third processed electrical signal S3, the sixth processed electrical signal N3, and the eighth processed electrical signal S5, a ninth processed electrical signal is S6, the ninth processed electrical signal S6 is transmitted to the electroacoustic transducer as an output signal of the signal processing unit, and the electroacoustic transducer is further configured to generate a noise reduction electrical signal according to a received electrical signal.

7. The noise reduction earphone of claim 4, wherein the signal processing unit further comprises a third signal processing circuit, a fourth signal processing circuit, and a second adder, the fourth signal processing circuit is configured to process the first electrical signal S1 and the third electrical signal N1, tenth a processed electrical signal is S7, the third signal processing circuit is configured to process the third processed electrical signal S3 and the sixth processed electrical signal N3, an eleventh processed electrical signal is S8, the second adder is configured to process the tenth processed electrical signal S7 and the eleventh processed electrical signal S8, a twelfth processed electrical signal is S9, the twelfth processed electrical signal S9 is transmitted to the electroacoustic transducer as an output signal of the signal processing unit, and the electroacoustic transducer is further configured to generate a noise reduction electrical signal according to a received electrical signal.

8. The noise reduction earphone of claim 1, wherein the noise reduction earphone further comprises a power amplifier, and the power amplifier is configured to amplify an output signal of the signal processing unit before the electroacoustic transducer.

9. The noise reduction earphone of claim 1, wherein the first signal processing circuit comprises a first gain adjuster and a first filter that are electrically connected, the second signal processing circuit comprises a second gain adjuster and a second filter that are electrically connected, a parameter of the first gain adjuster is Gain1, a parameter of the first filter is Filter1, a parameter of the second gain adjuster is Gain2, a parameter of the second filter is Filter2, the first processed electrical signal S11 is S1*Gain1*Filter1, the second processed electrical signal S12 is S2*Gain2*Filter2, and the third processed electrical signal S3 satisfies:
$$S 3 = S {1}^{*} {Gain 1}^{*} Filter 1 + S {2}^{*} {Gain 2}^{*} Filter 2 = 0 .$$

10. (canceled)

11. The noise reduction earphone of claim 6, wherein the fourth signal processing circuit comprises a third gain adjuster and a third filter that are electrically connected, a parameter of the third gain adjuster is Gain3, and a parameter of the third filter is Filter3.

12. (canceled)

13. The noise reduction earphone of claim 1, wherein the noise reduction earphone further comprises an ear hook and a battery portion, one end of the ear hook is connected to the sound emitting apparatus, and the other end of the ear hook is connected to the battery portion, and the ear hook is used to fix the noise reduction earphone on an ear.

14. The noise reduction earphone of claim 1, wherein the first cavity is provided with a first tuning hole and/or a sound short circuit tube is arranged between the first cavity and the second cavity.

15. A noise reduction earphone, comprising: a sound emitting apparatus, wherein the sound emitting apparatus comprises a cavity, an electroacoustic transducer, a microphone, and a signal processing unit;
the electroacoustic transducer is arranged in the cavity and divides the cavity into a first cavity and a second cavity, the first cavity is provided with a first sound outlet hole, and the second cavity is provided with a second sound outlet hole;
the microphone is arranged close to the second sound outlet hole and is configured to collect a sound signal of the electroacoustic transducer in the second cavity and convert the sound signal into a fifth electrical signal A2; and
the signal processing unit comprises a first signal processing circuit, a second signal processing circuit, and a first adder, the second signal processing circuit is configured to perform signal processing on the fifth electrical signal A2, and a thirteenth processed electrical signal is A12; the first signal processing circuit is configured to acquire a sixth electrical signal A before being transmitted to the electroacoustic transducer and process the sixth electrical signal A into a fourteenth electrical signal A11; the fourteenth electrical signal A11 and the thirteenth electrical signal A12 have equal amplitudes and opposite phases; and the first adder is configured to process the fourteenth processed electrical signal A11 and the thirteenth signal electrical signal A12, a fifteenth processed electrical signal is A3, the fifteenth processed electrical signal A3 is transmitted to the electroacoustic transducer as an output signal of the signal processing unit, and an amplitude of the fifteenth processed electrical signal A3 is zero.

16. A noise reduction earphone, comprising: a sound emitting apparatus, wherein the sound emitting apparatus comprises a cavity, an electroacoustic transducer is arranged in the cavity, the electroacoustic transducer divides the cavity into a first cavity and a second cavity, the first cavity is provided with a first sound outlet hole, and the second cavity is provided with a second sound outlet hole; a first microphone is arranged between the first sound outlet hole and the electroacoustic transducer, a second microphone is arranged on the sound emitting apparatus and is close to the second sound outlet hole, the first cavity is provided with a first tuning hole, a center distance between the first sound outlet hole and the first tuning hole is not greater than 6 mm, and a distance between a center of the second sound outlet hole and a center of the first sound outlet hole is not greater than 15 mm.

17. The noise reduction earphone of claim 16, wherein a vertical distance from a sound pickup hole of the first microphone to a straight line wherein a center point of the first sound outlet hole and a center point of the first tuning hole are located is not greater than 5 mm.

18-19. (canceled)

20. The noise reduction earphone of claim 16, wherein the first microphone and a sound pickup hole thereof are close to the first sound outlet hole.

21. The noise reduction earphone of claim 20, wherein the sound pickup hole of the first microphone faces towards a diaphragm of the electroacoustic transducer.

22.-24. (canceled)

25. The noise reduction earphone of claim 16, wherein the first sound outlet hole and the first tuning hole are arranged on a first surface of the first cavity, the first surface is a surface closest to a crus of helix in surfaces of the sound emitting apparatus when the user wears the noise reduction earphone, and the first sound outlet hole and the first tuning hole form acoustic coupling with the electroacoustic transducer through the first cavity.

26. (canceled)

27. The noise reduction earphone of claim 25, wherein the first surface has an arc-shaped design.

28. The noise reduction earphone of claim 27, wherein a convex structure is arranged on the first surface, an end surface is arranged on the convex structure, the first sound outlet hole is arranged in the end surface, and an included angle between a plane wherein the end surface is located and a plane wherein a diaphragm of the electroacoustic transducer is located is between 30 degrees and 60 degrees.

29. The noise reduction earphone of claim 28, wherein the convex structure has a certain arc-shaped design from the first surface to the end surface.

30. (canceled)

31. The noise reduction earphone of claim 16, wherein the noise reduction earphone further comprises a third microphone, and the third microphone and the second microphone cooperate with a directivity algorithm to form dual-microphone call noise reduction.

32-41. (canceled)
